(19) United States
(12) Patent Application Publication
(10) Pub. No.: US 2023/0356188 A1
(43) Pub. Date: Nov. 9, 2023

(54) LANTHANA AND ALUMINA OVERCOATED NICKEL CATALYSTS FOR ENHANCED METHANE REFORMING

(71) Applicant: Northwestern University, Evanston, IL (US)

(72) Inventors: Tobin J. Marks, Evanston, IL (US); Peter C. Stair, Santa Fe, NM (US); Patrick Littlewood, Chicago, IL (US); Sol Ahn, Evanston, IL (US)

(21) Appl. No.: 18/142,771

(22) Filed: May 3, 2023

Related U.S. Application Data
(60) Provisional application No. 63/338,138, filed on May 4, 2022.

(51) Int. Cl. B01J 23/755; C23C 16/455; B01J 37/02; B01J 21/04; B01J 23/10; C23C 16/40; C01B 3/40

(52) U.S. Cl. CPC B01J 21/04; B01J 23/10; B01J 23/755; B01J 37/0215; C01B 3/40; C23C 16/40; C23C 16/45527; C01B 2203/0238; C01B 2203/1082; C01B 2203/1241

(57) ABSTRACT

Catalyst systems are provided which, in embodiments, comprise an aluminum oxide support comprising nickel, a layer of a lanthanide oxide on a surface of the aluminum oxide support, and a layer of aluminum oxide on a surface of the layer of the lanthanide oxide. In other embodiments, a catalyst system comprises an aluminum oxide support comprising nickel, a plurality of lanthanide oxide microdomains on surfaces of the nickel of the aluminum oxide support, and aluminum oxide on surfaces of the plurality of lanthanide oxide microdomains. Methods of making and using the catalyst systems, e.g., in methane reforming reactions, are also provided.

### CROSS-REFERENCE TO RELATED APPLICATIONS

The present application claims priority to U.S. Provisional Pat. Application No. 63/338,138 that was filed May 4, 2022, the entire contents of which are incorporated herein by reference.

### BACKGROUND

Many heterogeneous catalysts suffer from deactivation over time due to coking and sintering during the catalytic reaction. Harsh operating reaction conditions, for example high temperatures or high chemical potentials, are likely to cause severe deactivation because such conditions can increase the rates of coke formation, agglomeration or sintering of active metal sites, and/or other deactivating processes. Dry reforming of methane (DRM) in which methane is used to reduce CO₂, is a classic example of an endothermic (ΔH_{298K} = + 247 kJ mol⁻¹) catalytic reaction requiring harsh conditions (operating temperature > 600-700° C.), resulting in severe catalyst deactivation. Despite these high energy requirements, this process has attracted significant attention because it converts both methane and carbon dioxide, two major greenhouse gases, into the valuable chemical feedstocks, CO and H₂. One significant deactivation mechanism for DRM catalysts is sintering of active metal sites, a high-temperature process by which the catalytically active metal atoms migrate (Ostwald ripening) and/or metal particles coalesce and form less and/or fewer active sites for the reaction (sintering). The initial deactivation of Ni/Al₂O₃ catalysts under DRM conditions has been reported to be caused by sintering of the Ni particles with an apparent activation energy of 161 kJ mol⁻¹. (See Littlewood, P., et al. Industrial & Engineering Chemistry Research 2019, 58 (7), 2481-2491.)

### SUMMARY

The present disclosure provides catalyst systems based on lanthanide oxide (e.g., lanthanum oxide) doping and aluminum oxide overcoating of alumina supported nickel catalysts. Embodiments of the catalyst systems exhibit remarkably high stability while also maintaining high activity. This is believed to be due to an unexpected synergy achieved when using both La₂O₃ doping and Al₂O₃ overcoating as described herein. Without wishing to be bound to any particular theory, it is believed that both the La₂O₃ doping and the Al₂O₃ overcoating as described herein achieves exposure of highly-coordinated (and thus, catalytically active) Ni atoms while inhibiting the formation of catalytically inactive NiAl₂O₄. These results and mechanisms are further described in the Example, below. Also provided are methods of making and using the catalyst systems.

In embodiments, a catalyst system comprises an aluminum oxide support comprising nickel, a layer of a lanthanide oxide on a surface of the aluminum oxide support, and a layer of aluminum oxide on a surface of the layer of the lanthanide oxide.

In embodiments, a catalyst system comprises an aluminum oxide support comprising nickel, a plurality of lanthanide oxide microdomains on surfaces of the nickel of the aluminum oxide support, and aluminum oxide on surfaces of the plurality of lanthanide oxide microdomains.

Methods of making and using the catalyst systems, e.g., in methane reforming reactions, are also provided.

Other principal features and advantages of the disclosure will become apparent to those skilled in the art upon review of the following drawings, the detailed description, and the appended claims.

### BRIEF DESCRIPTION OF THE DRAWINGS

Illustrative embodiments of the disclosure will hereafter be described with reference to the accompanying drawings.

FIGS. 1A-1D show schematic illustrations of catalysts: (FIG. 1A) Ni/Al₂O₃, (FIG. 1B) (Ni/Al₂O₃)@Al₂O₃20c, (FIG. 1C) (Ni/Al₂O₃)@La₂O₃8c, and (FIG. 1D) (Ni/Al₂O₃)@La₂O₃8c@Al₂O₃20c.

FIG. 2A plots weight percent of Ni obtained via ICP (squares) and XPS (circles) as a function of the number of Al ALD cycles on the (Ni/Al₂O₃)@La₂O₃8c catalyst and FIG. 2B plots the same results but with respect to La (see the inset for the ICP results).

FIG. 3A shows the BET DFT-analyzed pore size distribution of catalysts including Ni/Al₂O₃, (Ni/Al₂O₃)@La₂O₃8c, (Ni/Al₂O₃)@La₂O₃8c@Al₂O₃5c, (Ni/Al₂O₃)@La₂O₃8c@Al₂O₃10c, and (Ni/Al₂O₃)@La₂O₃8c@Al₂O₃20c). FIG. 3B shows the dependence of BET surface area (squares) and pore volume (circles) on the number of Al ALD cycles on (Ni/Al₂O₃)@La₂O₃8c.

FIG. 4A shows the activity of catalysts (Ni/Al₂O₃: open circles, (Ni/Al₂O₃)@La8c: open squares, (Ni/Al₂O₃)@La₂O₃8c@Al₂O₃5c: open triangles, (Ni/Al₂O₃)@La₂O₃8c@Al₂O₃10c: closed diamonds, (Ni/Al₂O₃)@La₂O₃8c@Al₂O₃20c: closed circles, and (Ni/Al₂O₃)@Al20c: closed squares. FIG. 4B shows normalized activity to compare deactivation behavior.

FIG. 5 shows the effect of the number of Al₂O₃ ALD cycles on (Ni/Al₂O₃)@La₂O38c DRM peak reaction rate (squares) and the long-term deactivation constant (triangles).

FIG. 6 shows the powder x-ray diffraction spectra of synthesized catalysts.

FIG. 7 shows the mass gain as a function of number of Al ALD cycles on (Ni/Al₂O₃)@La₂O₃8c.

### DETAILED DESCRIPTION

In embodiments, a catalyst system comprises an aluminum oxide support comprising nickel, a layer of a lanthanide oxide on a surface of the aluminum oxide support, and a layer of aluminum oxide on a surface of the layer of the lanthanide oxide. The lanthanide of the lanthanide oxide may be any lanthanide element. In embodiments, the lanthanide element is selected from La, Pr, Nd, Pm, Sm, Gd, Tb, Dy, Ho, Er, Tm, Yb, and Lu and the lanthanide oxide is an oxide of the selected lanthanide element. In embodiments, the lanthanide element is La (lanthanum) and the lanthanide oxide is lanthanum oxide (which may be referred to as lanthana or La₂O₃). A single type of lanthanide oxide or multiple types of lanthanide oxides (i.e., a mixture of different types of lanthanide oxides) may be used. Embodiments below are described with respect to a specific, single type of lanthanide oxide (lanthanum oxide). However, the present disclosure encompasses analogous embodiments involving other types of lanthanide oxides and mixtures of different types of lanthanide oxides.

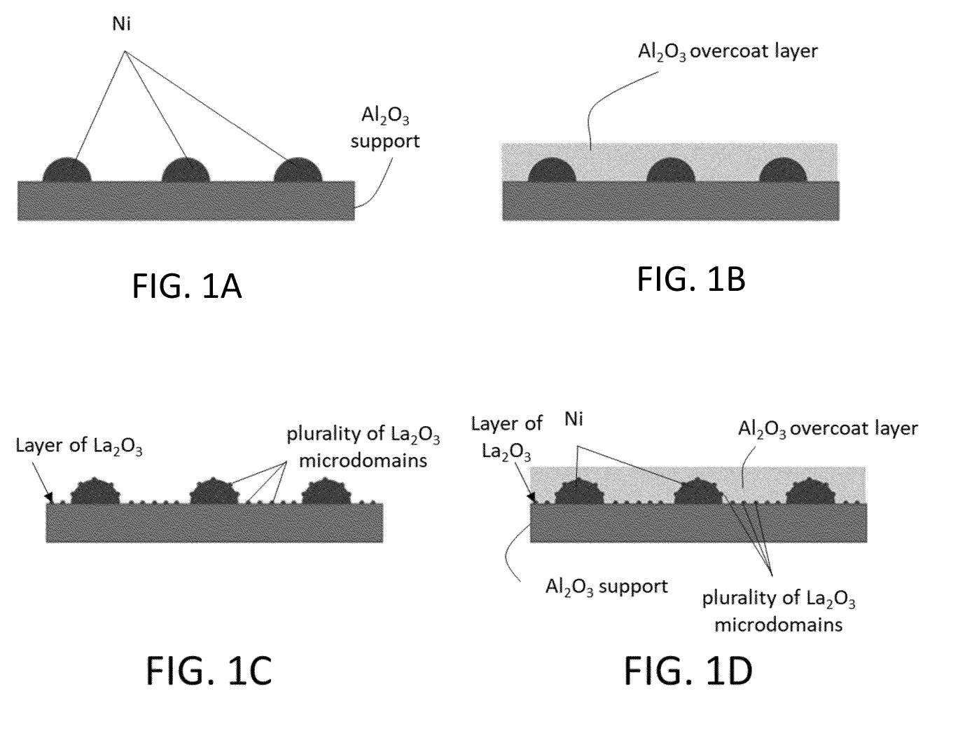

Thus, in embodiments, a catalyst system comprises an aluminum oxide support comprising nickel, a layer of lanthanum oxide on a surface of the aluminum oxide support, and a layer of aluminum oxide on a surface of the layer of lanthanum oxide. The aluminum oxide support comprising nickel may be formed using incipient wetness impregnation as described in the Example below. This process results in a plurality of nickel atoms and/or nickel particles distributed on a surface of the aluminum oxide support. (See FIG. 1A). The nickel is generally evenly distributed across the surface of the aluminum oxide support (itself which may be in the form of micron-sized, e.g., 100 µm to 400 µm, particles of Al₂O₃). The nickel is in direct contact with the aluminum oxide of the aluminum oxide support, but a portion of the nickel remains exposed to form other interfaces with overlying materials (e.g., the layer of lanthanum oxide and the layer of aluminum oxide) as described below. The amount of nickel in the catalyst system may be in a range of from 1 weight% to 20 weight% (as compared to the total weight of the nickel-containing aluminum oxide support). This includes from 1 weight% to 15 weight%, from 1 weight% to 10 weight%, and from 1 weight% to 5 weight%.

The layer of lanthanum oxide on the surface of the aluminum oxide support is preferably formed using atomic layer deposition (ALD). This is accomplished by exposing the aluminum oxide support comprising nickel to cycles of alternating pulses of a lanthanum precursor (e.g., tris(2,2,6,6-tetramethyl-3,5-heptanedionato)lanthanum) and an oxygen precursor (e.g., ozone) under conditions to induce reactions between the precursors to form lanthanum oxide on the surface of the aluminum oxide support. (“Lanthanum precursor” refers to a molecule comprising lanthanum; “oxygen precursor” refers to a molecule comprising oxygen.) The number of cycles may be adjusted to provide a desired amount of lanthanum (or lanthanum oxide), a certain morphology (e.g., the plurality of microdomains described below), a desired thickness, as well as to tune catalyst activity and stability. In embodiments, the number of cycles is in a range of from 2 to 20, from 3 to 15, or from 4 to 12. Additional, illustrative details for the growth of the lanthanum oxide layer via ALD may be found in the Example, below.

The lanthanum oxide layer need not (and generally does not) completely cover the underlying aluminum oxide support (or nickel atoms/particles thereon). (See FIG. 1C.) The term “layer” encompasses the lanthanum oxide being in the form of a plurality of microdomains distributed on the surface of the aluminum oxide support, including surfaces of the nickel atoms/particles thereon. The term “microdomains” is used to describe discrete and separated regions of lanthanum oxide as distinguished from a generally continuous layer of lanthanum oxide. However, the term “microdomains” is not intended to connote a particular size or shape, as the term encompasses regions formed by individual lanthanum oxide molecules as well as regions formed by a plurality of lanthanum oxide molecules. Nevertheless, generally, the lateral (i.e., in plane) size of the microdomains is quite small, e.g., less than 1 nm, less than 0.5 nm, less than 0.1 nm, or an individual lanthanum oxide molecule. The lanthanum oxide microdomains are distributed on the surface of the aluminum oxide support, which may result in at least some lanthanum oxide microdomains being in direct contact with the nickel atoms/particles of the aluminum oxide support, while others may be in direct contact with the aluminum oxide of the aluminum oxide support. Both types of lanthanum oxide microdomains may have a portion of their surfaces which remain exposed to form other interfaces with overlying materials (e.g., the layer of aluminum oxide) as described below.

However, as further described below, the use of ALD to form the lanthanum oxide layer is believed to enable the preferential binding of the lanthanum oxide of the lanthanum oxide layer to under-coordinated sites (e.g., under-coordinated NiO) present in the aluminum oxide support. Terms such as “coordination” and the like refer to the number of nearest neighbors to the relevant site (e.g., a Ni atom, or a NiO molecule). The specific coordination number depends upon the site as well as the local geometry. By way of illustration, with respect to Ni, “highly-coordinated” encompasses Ni atoms on (111) Miller Index faces having a coordination number of at least 7, at least 8, or at least 9. Highly-coordinated Ni atoms are highly catalytically active. “Under-coordinated” encompasses Ni atoms, e.g., at step edges and corners, which may have coordination numbers of less than 7, including as small as 3. Under-coordinated atoms, with fewer bonds anchoring them, are more easily detached, contributing to the sintering of metal particles via Ostwald Ripening.

The lanthanum oxide layer may be characterized by the position of the lanthanum oxide therein (including in the form of lanthanum oxide microdomains) relative to the underlying aluminum oxide support. Specifically, the lanthanum oxide may be positioned on the nickel (including on under-coordinated sites therein) of the aluminum oxide support. In embodiments, more of the lanthanum oxide is positioned on the nickel rather than on the aluminum oxide. In embodiments, at least 40%, at least 50%, at least 75%, or at least 90% of the lanthanum oxide is positioned on the nickel rather than on the aluminum oxide. This concentration of the lanthanum oxide on the surfaces of the nickel atoms/particles, rather than on the aluminum oxide of the aluminum oxide support, means that the lanthanum oxide layer may be characterized as having a non-uniform distribution of the lanthanum oxide therein, which may be evidenced, e.g., via high resolution transmission electron microscope (TEM) images.

The lanthanum oxide layer may have a thickness of no more than 1 nm, no more than 0.8 nm, or no more than 0.6 nm. This includes a thickness of from greater than 0 nm to no more than 1 nm. In embodiments in which the layer is in the form of a plurality of microdomains, this thickness may be the average thickness of the microdomains from which the layer is composed.

The amount of lanthanum in the catalyst systems is also relatively small, e.g., from 0.5 weight% to 5 weight% (as compared to the total weight of nickel). This includes from 1 weight% to 5 weight% and from 0.5 weight% to 2 weight%. The lanthanum that is present in the catalysts systems is also generally confined to the surface of the aluminum oxide support rather than being incorporated within the lattice of the aluminum oxide support (i.e., within bulk aluminum oxide). In embodiments, the amount of lanthanum within the aluminum oxide support is not more than 0.1 weight%, not more than 0.05 weight%, or not more than 0.03 weight% (as compared to the total weight of lanthanum).

The layer of aluminum oxide (which may also be referred to as an “overcoating” and like terms) on the surface of the lanthanum oxide layer is also preferably formed using ALD. This may be accomplished by exposing the lanthanum oxide deposited aluminum oxide support comprising nickel to cycles of alternating pulses of an aluminum precursor (e.g., trimethyl aluminum) and an oxygen precursor (e.g., water) to induce reactions between the precursors to form aluminum oxide on the underlying layer(s). (“Aluminum precursor” refers to a molecule comprising aluminum; “oxygen precursor” refers to a molecule comprising oxygen.) The number of cycles may be adjusted to provide a desired thickness of the aluminum oxide layer as well as to tune catalyst activity and stability. In embodiments, the number of cycles is in a range of from 5 to 30, from 7 to 27, from 8 to 24, from 1 to 10, from 2 to 10, from 3 to 10, or from 3 to 8. Additional, illustrative details for the growth of the aluminum oxide layer via ALD may be found in the Examples, below.

The resulting ALD-grown aluminum oxide layer is also generally quite thin. In embodiments, the aluminum oxide layer has a thickness of from 0.2 nm to 10 nm. This includes from 0.2 nm to 8 nm and from 0.2 nm to 4 nm. As described in the Example, below, the thickness may be determined from the number of ALD cycles and the ALD growth rate. As shown in FIG. 1D, the aluminum oxide layer may be in direct contact with both microdomains of the lanthanum oxide layer as well as portions of the aluminum oxide support (and nickel atoms/particles thereon) not covered by the microdomains of the lanthanum oxide layer. Thus, FIG. 1D shows a generally continuous aluminum oxide layer, but this embodiment is not intended to be limiting. In other embodiments, a portion of surfaces of nickel atoms/particles and/or a portion of surfaces of lanthanum oxide microdomains and/or a portion of surfaces of aluminum oxide of the aluminum oxide support may remain exposed. Moreover, like the lanthanum oxide layer, the aluminum oxide of the aluminum oxide layer may also be in the form of a plurality of microdomains. In that case, the description of the microdomains described above with respect to the lanthanum oxide layer may be applied analogously to the aluminum oxide layer, although the lateral size of the aluminum oxide microdomains may be greater, e.g., 10 nm.

In addition, as further described below, use of ALD to form the aluminum oxide overcoating is believed to enable the preferential binding of the aluminum oxide to the previously formed lanthanum oxide (including in the form of lanthanum oxide microdomains). This, in turn, positions the aluminum oxide at or near the locations of the under-coordinated sites present in the aluminum oxide support, leaving the highly-coordinated Ni atoms exposed and available to facilitate the catalytic reactions described herein (e.g., dry methane reforming). Thus, the aluminum oxide overcoating may be characterized by the position of the aluminum oxide (including in the form of aluminum oxide microdomains) therein. Specifically, the aluminum oxide of the overcoating may be positioned on the previously formed lanthanum oxide. In embodiments, more of the aluminum oxide of the overcoating is positioned on the previously formed lanthanum oxide, and possibly, the nickel, rather than on the aluminum oxide of the aluminum oxide support. In embodiments, at least 40%, at least 50%, at least 75%, or at least 90% of the aluminum oxide of the overcoating is positioned on the previously formed lanthanum oxide, and possibly, the nickel, rather than on the aluminum oxide of the aluminum oxide support. This concentration of the aluminum oxide of the overcoating on previously formed lanthanum oxide, and possibly, surfaces of the nickel atoms/particles, rather than on the aluminum oxide of the aluminum oxide support, means that the aluminum oxide overcoating may be characterized as having a non-uniform distribution of the aluminum oxide therein, which may be evidenced, e.g., via high resolution TEM images.

In embodiments, the catalyst system consists of the nickel of the aluminum oxide support, the Al₂O₃ of the aluminum oxide support, the layer of La₂O₃ (which may be in the form of a plurality of La₂O₃ microdomains) and the layer of Al₂O₃. However, such embodiments encompass a minor amount of impurities in the catalyst system inherent to the synthetic techniques described herein.

In addition to the description above, the Example below illustrates methods of making the present catalyst systems. Briefly, a method of making the present catalyst systems may comprise exposing the aluminum oxide support comprising nickel to cycles of alternating pulses of a lanthanide precursor and a first oxygen precursor under conditions to induce reactions between the precursors to form a lanthanide oxide via ALD, thereby forming a layer of the lanthanide oxide on the surface of the aluminum oxide support; and exposing the layer of the lanthanide oxide on the surface of the aluminum oxide support to cycles of alternating pulses of an aluminum precursor and a second oxygen precursor under conditions to induce reactions between the precursors to form aluminum oxide via ALD, thereby forming a layer of aluminum oxide on the layer of the lanthanide oxide. The method may further comprise making the aluminum oxide support comprising nickel, e.g., via wetness impregnation using a nickel salt and aluminum oxide, prior to ALD of the layer of the lanthanide oxide and the layer of aluminum oxide. The method can, but need not, comprise calcining (e.g., heating in N₂, O₂, air, etc.) the catalyst system prior to reduction or prior to use in a catalytic reaction (e.g., dry reforming of methane). If such calcining is used it may be carried out using a temperature of 600° C. or less, 550° C. or less, or 500° C. or less. In embodiments, such calcining is not used.

The present catalyst systems may be used in various methods, including the reforming of methane. In embodiments, a method of reforming methane comprises exposing any of the present catalyst systems to methane and an oxygen containing compound at an elevated temperature and for a period of time to convert the methane to products. In steam methane reforming, the oxygen containing compound is water and the products comprise H₂, CO, and CO₂. In dry methane reforming, the oxygen containing compound is CO₂ and the products comprise H₂ and CO (synthesis gas). In other embodiments, both H₂O and CO₂ may be used together as the oxygen containing compounds. Reaction temperatures, reaction times, reactor systems, and other conditions generally used in methane reforming may be used in the present disclosure.

The present catalyst systems may be characterized by properties such as activity and stability. These properties may be referenced with respect to a particular catalytic reaction as well as a particular set of reaction conditions (e.g., dry methane reforming and the conditions used in the Example below). Activity may be quantified via a peak reaction rate, measured as described in the Example, below. Stability may be quantified via a short-term deactivation constant, a long-term deactivation constant, and an overall fraction/percentage of peak activity as described in the Example, below. As demonstrated in Example below (see Table 1), the present catalyst systems are able to strike an advantageous balance between activity and stability in the dry reforming of methane. This Example further discusses the unexpectedly high activity and stability of a specific catalyst system, (Ni/Al₂O₃)@La8c@Al₂O₃5c in the dry reforming of methane.

Without wishing to be bound to any particular theory, it is believed that use of ALD to form the lanthanum oxide layer (in which the lanthanum oxide forms via the chemical reactions taking place on the surface of the aluminum oxide support as described above) results in the lanthanum oxide preferentially binding to under-coordinated sites present in the aluminum oxide support. This, in turn, induces the aluminum oxide of the ALD-grown overcoating to preferentially bind to the lanthanum oxide at these under-coordinated sites, thereby leaving more highly-coordinated Ni atoms present in the aluminum oxide support exposed and available to facilitate the catalytic reactions described herein (e.g., dry methane reforming). By contrast, other techniques, e.g., sol-gel, impregnation, cannot direct the binding of lanthanum oxide in this way due to the different chemistry involved. Thus, use of ALD to form the lanthanum oxide layer results in the present catalyst systems being chemically/physically distinguished from existing catalyst systems, thereby rendering the present catalyst systems with improved activity and stability.

### EXAMPLE

### Introduction

Deposition of La₂O₃ and Al₂O₃ on Al₂O₃-supported Ni catalysts was performed to study their effects on the stabilization of heterogeneous catalysts for the dry reforming of methane (DRM) reaction. An alumina-supported Ni catalyst (Ni/Al₂O₃, 2 wt.% of Ni), synthesized via incipient wetness impregnation, loses ~87% of its initial activity within 45 h under DRM conditions. While overcoating of Al₂O₃ on this catalyst via atomic layer deposition (ALD) helps stabilize the catalyst in long time-on-stream (TOS) tests, this overcoated catalyst is ~40 times less active than the uncoated catalyst at peak activity. This Al₂O₃ overcoated Ni/Al₂O₃ catalyst also exhibits a long induction period (~20 h) due to slow reduction of the Ni²⁺ within the catalytically inactive nickel aluminate (NiAl₂O₄) phase, formed by interaction of metallic Ni with the Al₂O₃ overcoat at the 700° C. reaction temperature.

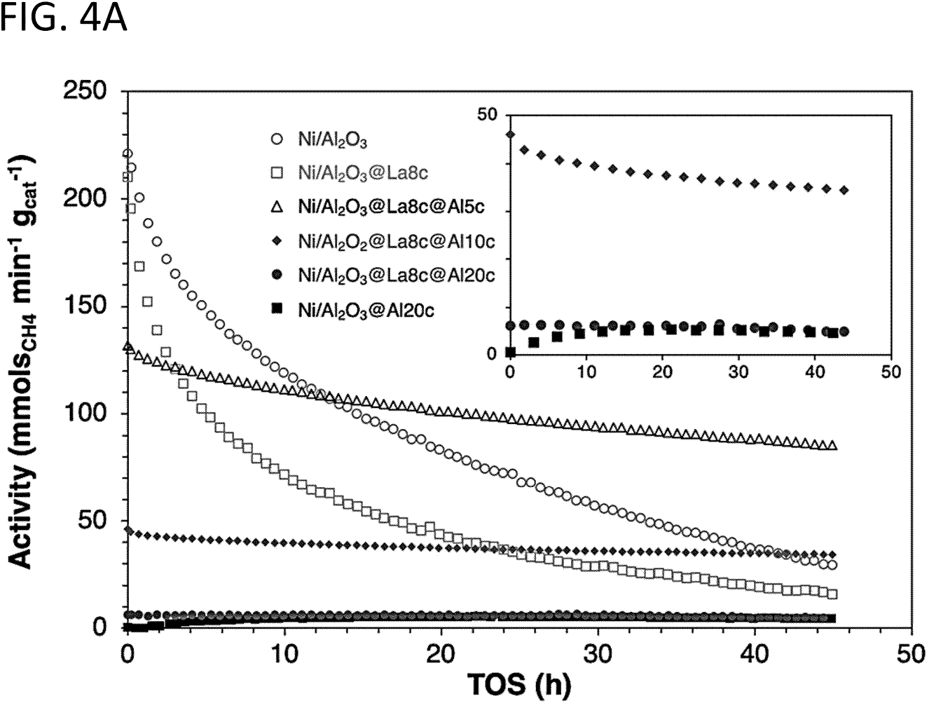

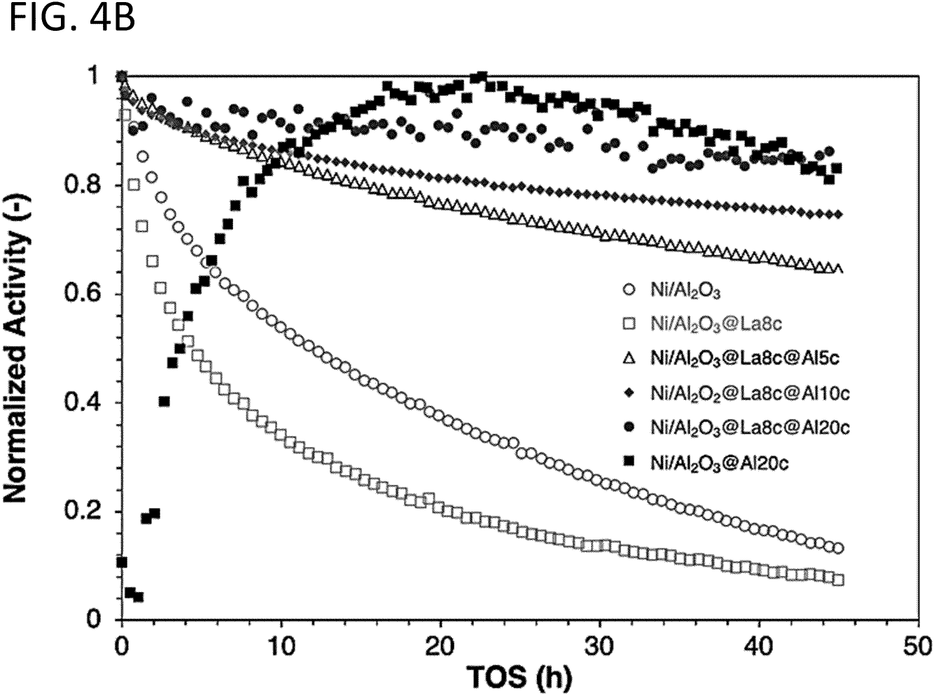

In this Example, it is demonstrated that doping small amounts of La (~0.03 wt.% of atomic La) into the Ni/Al₂O₃ catalyst does not significantly affect the catalytic activity nor stability due to the lack of Al₂O₃ overcoating stabilization benefits. However, an unexpected synergy was observed when adding an Al₂O₃ overcoating on top of the La₂O₃ promoted Ni catalyst, as demonstrated by a substantial reduction in the short-term deactivation of the catalyst, a substantial reduction in long TOS deactivation, a substantial recovery of the peak activity, and elimination of an induction period. (See FIGS. 4A-4B and Table 1, which are further discussed below.) In summary, this Example reports an La₂O₃ doping strategy via ALD that achieves the stabilization benefits of Al₂O₃ overcoating on Ni/Al₂O₃ while, at the same time, maintaining catalytic activity and avoiding the formation of undesirable NiAl₂O₄ species.

### Experimental

Catalysts Synthesis. An alumina supported Ni DRM catalyst (Ni/Al₂O₃) was synthesized via incipient wetness impregnation of the Ni precursor solution (Ni(NO₃)₂·6H₂O, Sigma Aldrich) on the alumina support, and then calcined in static air at 550° C. for 2 h with a ramp rate of 5° C. min⁻¹. (See Littlewood, P.; et al., Catalysis Today 2020, 343, 18-25.)

La₂O₃ ALD was carried out in a custom-built ALD instrument, using tris(2,2,6,6-tetramethyl-3,5-heptanedionato)lanthanum (La(thd)₃) (Strem Chemicals) as the La precursor. The La precursor bubbler was heated at 180° C. to ensure sufficient vapor pressure for deposition. All lines were heated at 200° C. to prevent precursor condensation in the ALD system. A 100 mg charge of Ni/Al₂O₃ was placed in the ALD chamber, which was heated at 300° C. For one cycle of La₂O₃ ALD, a valve from the La precursor bubbler to the reaction chamber opened for 10 min for dose and hold, and then closed for 10 min for purging of remaining La precursor. Then, a valve connected to an O₃ generator (Pacific Ozone) was opened for 10 min to allow ozone (the oxygen precursor) to flow into the reaction chamber, and lastly the O₃ valve was closed for 10 min for purge. This cycle was repeated for 8 cycles, and the resulting material is denoted as (Ni/Al₂O₃)@La₂O₃8c.

Al₂O₃ ALD was performed on (Ni/Al₂O₃)@La₂O₃8c, and is denoted as (Ni/Al₂O₃)@La₂O₃8c@Al₂O₃Xc (X= 0, 5, 10, and 20). See FIGS. 1A-1D for schematic illustrations of the resulting materials. Al₂O₃ ALD was performed in Gemstar ALD (Arradiance) reactor. (See Baktash, E.; et al., Applied Catalysis B: Environmental 2015, 179, 122-127.) Briefly, (Ni/Al₂O₃)@La₂O₃8c was placed in the ALD chamber (heated at 125° C.), and then maintained under an N₂ flow for 20 min to equilibrate the sample temperature with the chamber temperature. Trimethyl aluminum (TMA, bubbler at ambient temperature, 1 sec for dose, 30 sec for hold, and 60 sec for corresponding purge) was used as the Al precursor, and H₂O (the oxygen precursor) (bubbler at ambient temperature, 1 sec for dose, 30 sec for hold, and 60 sec for purge) was pulsed to regenerate grafting sites (i.e., surface hydroxyl) for the next TMA pulse. Multiple cycles (X = 0, 5, 10, 20) of TMA/H₂O were performed to overcoat samples with Al₂O₃. There were no further treatments applied to these ALD treated samples before loading in the quartz catalytic reactor tube.

N₂ physisorption measurements. Prior to N₂ physisorption isotherm collection, samples were degassed at 150° C. until the rate of pressure change was below 0.001 mmHg/min on the Smart VacPrep (Micromeritics) instrument. N₂ adsorption and desorption isotherms were then collected at the normal boiling temperature of liquid nitrogen on a 3Flex BET device (Micromeritics). Surface area was calculated by BET equation, and pore size distribution was calculated by DFT method embedded in the measurement software. These experiments were performed in the Reactor Engineering and Catalyst Testing (REACT) core facility at Northwestern University.

Inductively Coupled Plasma-Optical Emission Spectroscopy (ICP-OES). ICP-OES spectra were recorded using an iCAP 7600 ICP-OES analyzer calibrated with standard solutions. Samples were added in concentrated mixture of HNO₃ (200 µL) and HCl (200 µL), and then heated at 65° C. After that, 2-5 mL of HF was added, and allowed to cool down to ambient temperature, and held until completely dissolved. [CAUTION: The use of HF must follow strict safety protocols.] Dissolved mixtures were diluted to a final volume of 11 mL with Millipore H₂O and analyzed for Ni (221.647, 231.604, and 341.476 nm) and La (333.749, 379.478, and 412.323) content.

X-ray Photoelectron Spectroscopy (XPS). XPS spectra were recorded at the Keck-II facility at Northwestern University with an ESCALAB 250 Xi spectrometer (Thermo Scientific), equipped with an Al K alpha radiation source and electron flood-gun, at a pressure of 8×10⁻⁸ mbar with a pass energy of 50 eV. Typically, a 20 ms dwell time and 5 scans were used for each spectrum. All spectra were calibrated according to the carbon peak at 284.8 eV. Elemental compositions were acquired from the survey scans.

Powder X-ray Diffraction (PXRD). PXRD data were collected at room temperature on a STOE-STADI-P powder diffractometer equipped with an asymmetric curved Germanium monochromator (CuKα1 radiation, λ = 1.54056 Å) and a one-dimensional silicon strip detector (MYTHEN2 1 K from DECTRIS). The line focused Cu X-ray tube was operated at 40 kV and 40 mA. Powder was packed in a 3 mm metallic mask and sandwiched between two polyimide or acetate layers of tape. Intensity data from 8 to 90 degrees 2θ were collected over a period of 3 mins step time with 0015 degrees of step size. Instrument was calibrated against a NIST Silicon standard (640d) prior the measurement.

Catalysis. A custom-built plug flow reactor was used to test the DRM activity of samples. Reactor temperature and flow rate were controlled by LabVIEW software. As-synthesized samples were loaded in the quartz reactor tube, and then reduced at 700° C. for 1 h under H₂ flow (50 mL/min) with 5° C./min ramp rate. Then, the gas flow was switched to the reaction mixture, which was 10% CH₄, 10% CO₂, and balance He (120 mL/min of total flow rate). Because the catalysts had widely varying specific activities, the catalyst amount (typically around 10 mg) was varied to achieve conversion of reactant below the DRM reaction thermodynamic equilibrium at the reaction temperature, and diluted in high purity quartz sand (99.999%, 400 mg) to minimize thermal gradients in the catalyst bed. The reactor outlet was directly connected to a GC (Agilent 3000A microGC) equipped with thermal conductivity detectors (TCD) on two channels (Ar, He). Reactants and products were identified and calibrated by using known concentration of standard gas cylinders, and they were quantified via TCD. Deactivation constants were obtained via slopes of linear fitting in short-term and long-term regimes of catalysts activity plots.

In order to calculate the growth rate of Al₂O₃ overcoat layer, the following equation was used.

$$\begin{matrix}\frac{m a s s g a i n \left(g\right)}{d e n s i t y \left(g / c {m}^{3}\right)} \times \frac{1}{s u r f a c e a r e a \left(c {m}^{2} / g\right) ⋅ \left(0.1 g\right)} \times \\ \frac{1}{\# o f A L D c y c l e s} = g r o w t h r a t e \left(c m / c y c l e\right)\end{matrix}$$

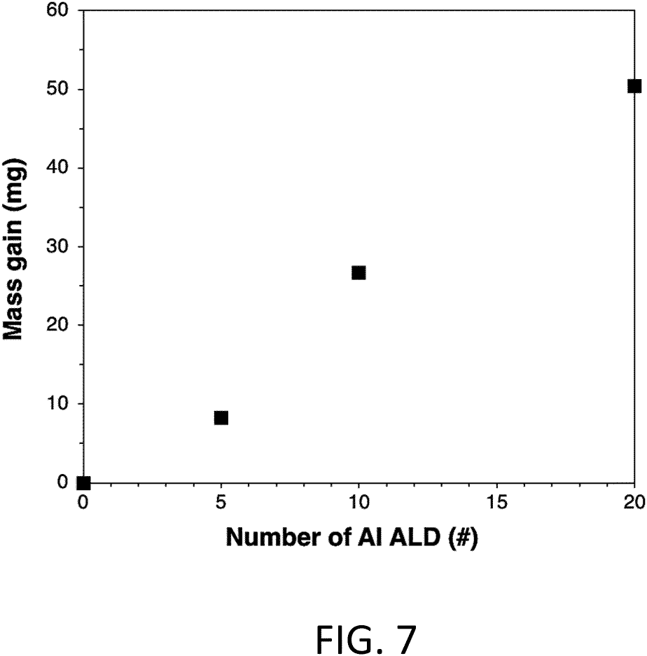

Here, the density of Boehmite (3 g/cm³) was used to estimate the density of Al₂O₃ overcoat layer. Mass gain was measured on balance after deposition of Al₂O₃ via ALD. (See FIG. 7.) These mass gain values were normalized based on the mass of starting material ((Ni/Al₂O₃)@La₂O₃8c) as 100 mg. Surface area of (Ni/Al₂O₃)@La₂O₃8c (89 m²/g) was used to obtain growth rates, assuming uniform growth per ALD cycles. Three growth rates were obtained (0.62, 0.99, and 0.94 Å/ALD cycle), and then averaged.

### Results and Discussion

FIGS. 1A-1D presents schematic illustrations of synthesized catalysts. As described above, Ni was deposited on the Al₂O₃ support via incipient wetness impregnation to form Ni/Al₂O₃ catalysts (FIG. 1A) and then an Al₂O₃ overcoat layer was deposited via ALD (FIG. 1B) to form the Ni/Al₂O₃@AlX (X = 5c, 10c, 20c) catalysts. La₂O₃ was deposited on Ni/Al₂O₃ via ALD (FIG. 1C) to form the (Ni/Al₂O₃)@La₂O₃8c catalysts, and next an Al₂O₃ overcoat layer was deposited via ALD to form the (Ni/Al₂O₃)@La₂O₃8c@AlX catalysts (FIG. 1D).

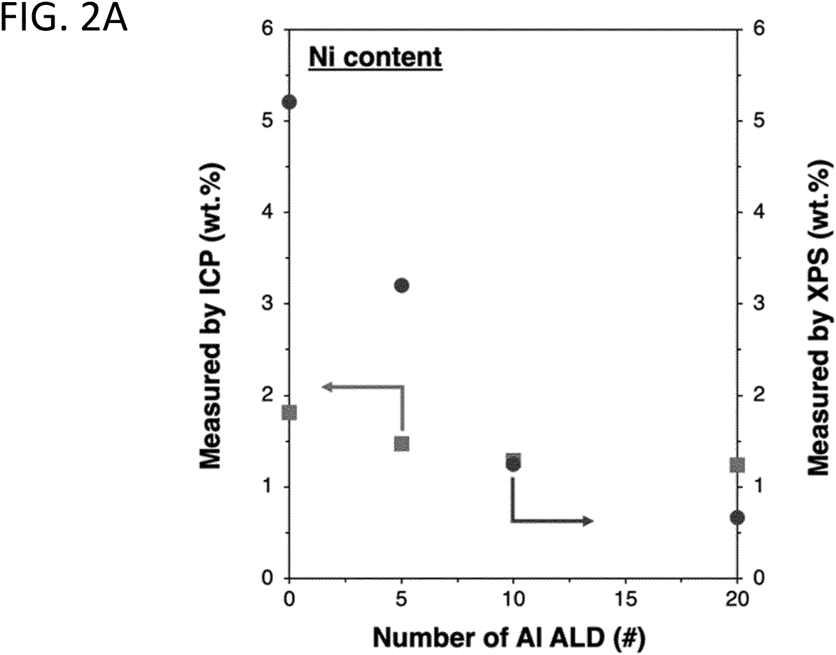

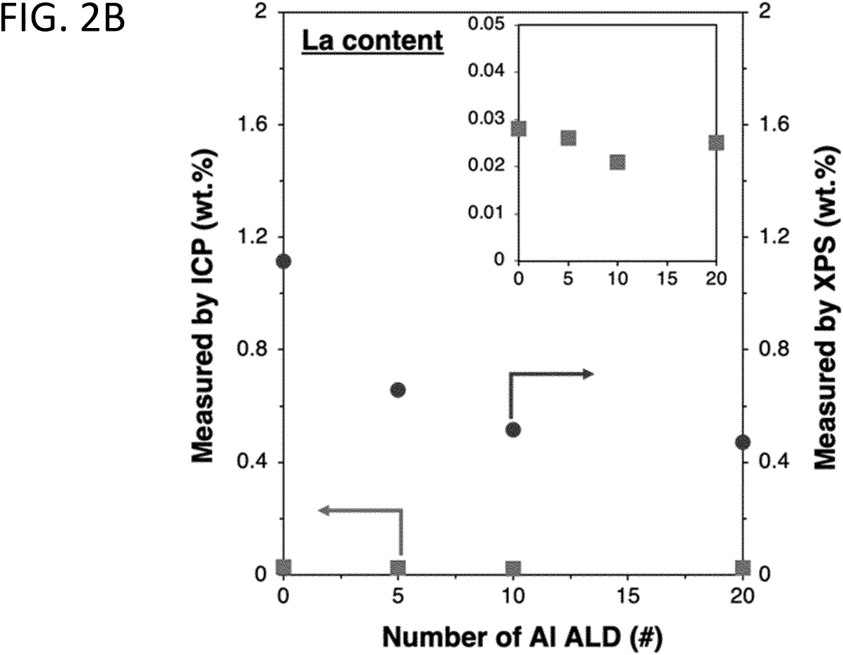

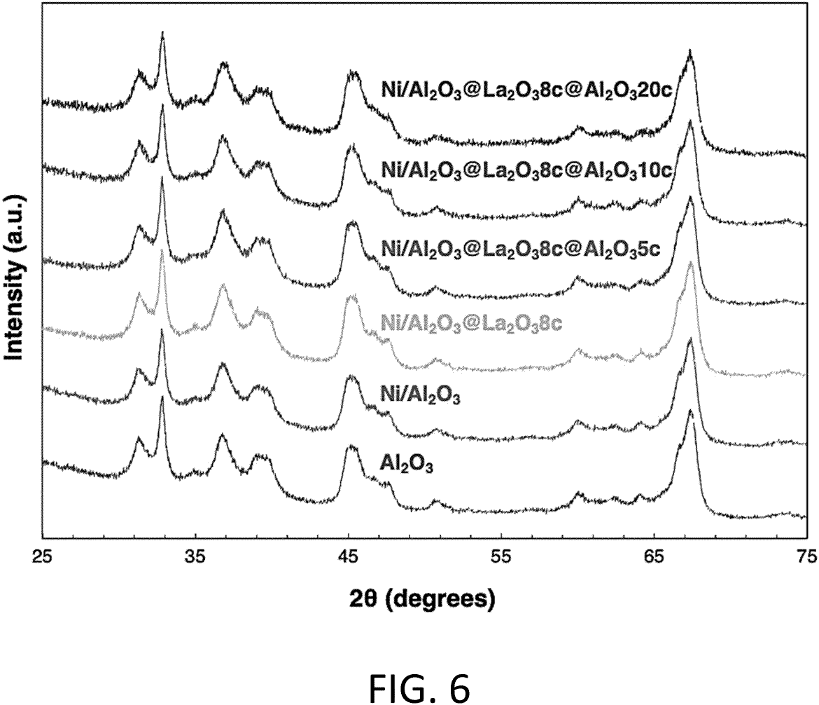

FIG. 2A shows that the amount of Ni as measured by ICP falls from 1.91 to 1.24 wt.% as the number of Al₂O₃ overcoat cycles increases. This reflects the increase in Al mass upon Al₂O₃ ALD overcoating. FIG. 2B shows that a very small amount of La₂O₃ was doped (~ 0.03 wt.% bulk basis La, see the inset of FIG. 2B) onto the Ni/Al₂O₃. XPS was also used to determine the amount of Ni and La by analyzing survey scans of the catalysts. Since XPS is a surface sensitive technique, and both ALD and incipient wetness impregnation methods deposit metal oxides on the surface rather than in the bulk, amounts of La analyzed by XPS are much higher than values measured by ICP, and this also applies for Ni. The results confirm that La₂O₃ is located on the surface rather than in the bulk phase. The amount of Ni measurable on the surface decreases rapidly upon Al₂O₃ overcoating with increasing numbers of ALD cycles, suggesting that the Al₂O₃ layer covers Ni atoms on the surface. This contact of Ni and Al₂O₃ prevents active Ni sites from agglomeration. In addition, XRD spectra reveal no evidence of large Ni particles or any La particles (see FIG. 6). Even after the DRM reaction there are no measurable diffraction features consistent with Ni and La particles. This demonstrates that Ni and La₂O₃ are well dispersed in all catalysts.

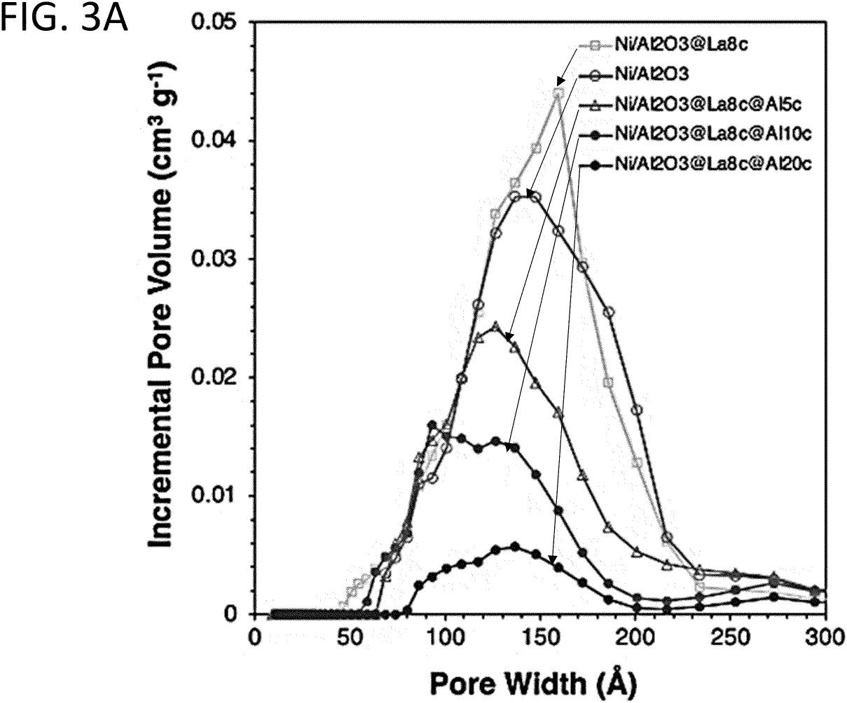

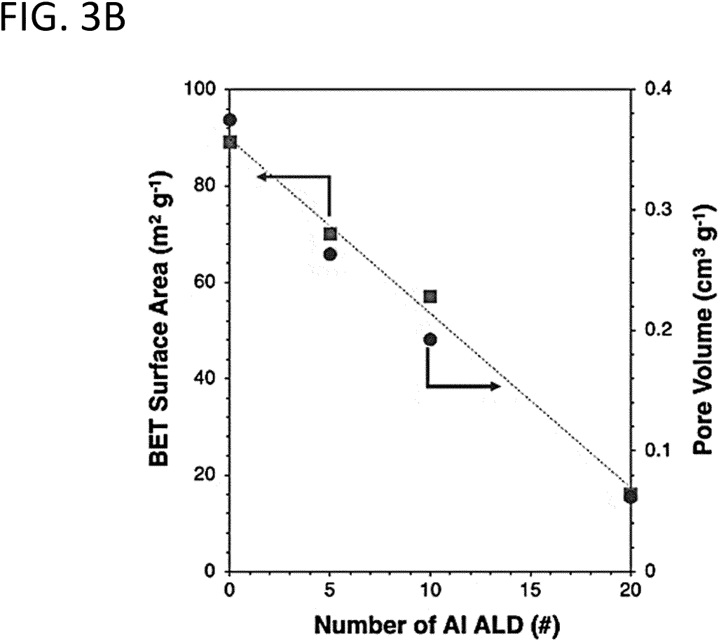

As shown in FIG. 3A, overcoating Ni/Al₂O₃@La₂O₃8c with ALD Al₂O₃ reduces the pore volumes by forming a thin, conformal layer. The peak positions of the pore size distribution become smaller as the number of Al₂O₃ ALD cycles increases, confirming thin layer deposition by the ALD. As shown in FIG. 3B, it can be seen that the BET surface area and pore volume fall monotonically with the number of Al₂O₃ ALD cycles. Assuming the same growth rate of each ALD cycle on the surface of (Ni/Al₂O₃)@La₂O₃8c and considering mass gain, the calculated Al₂O₃ growth rate is 0.9 Å/ALD cycle (See above for the detailed calculation method).

To test and compare the stability of the present catalysts under DRM conditions at 700° C., all catalysts were subjected to the same gas flow rates and gas compositions, but with varied quantities of catalyst loaded to ensure that the conversion was below the thermodynamic equilibrium conversion. Results are presented in Table 1, below, and shown in FIGS. 4A-4B. The bare Al₂O₃ support itself was tested, and found to be inactive for DRM. In contrast, Ni/Al₂O₃ exhibits the highest peak activity (217.15 mmols_{CH4} min⁻¹ g_{cat}⁻¹) among tested catalysts, but this catalyst loses ~50% of its activity within 15 h TOS. The primary reason for this deactivation under these reaction conditions is sintering of the Ni particles.

Addition of La₂O₃ via ALD on the Ni/Al₂O₃ catalyst does not significantly alter the peak activity (201.58 mmols_{CH4} min⁻¹ g_{cat}⁻¹) and does not enhance stability; rather, the La₂O₃-doped catalyst deactivates more severely than Ni/Al₂O₃ in the short-term (short-term deactivation constant is 89.8 × 10⁻³ h⁻¹). Thus, La₂O₃ addition alone is not effective in preventing sintering. However, La₂O₃ doping of Ni/Al₂O₃ followed by 5 cycles of ALD Al₂O₃ coating significantly improves the catalyst stability by reducing the short-term deactivation constant (89.8 × 10⁻³ h⁻¹ to 19.6 × 10⁻³ h⁻¹). The peak activity of the equivalent catalyst without La₂O₃, (Ni/Al₂O₃)@Al5c) is 16.51 mmols_{CH4} min⁻¹ g_{cat}⁻¹,²¹ while in the presence of La₂O₃ ((Ni/Al₂O₃)@La₂O₃8c@Al5c), the peak rate increases to 131.91 mmols_{CH4} min⁻¹ g_{cat}⁻¹. This is about 8-fold higher than the catalyst without La₂O₃ ((Ni/Al₂O₃)@Al5c). Therefore, while the Al₂O₃ overcoating results in activity loss, the presence of La₂O₃ substantially reduces the extent of this activity loss. In addition, the presence of La₂O₃ helps stabilize Al₂O₃ overcoated catalysts, as the short-term deactivation constant decreases from 52.1 × 10⁻³ h⁻¹ ((Ni/Al₂O₃)@Al5c) to 19.6 × 10⁻³ h⁻¹ ((Ni/Al₂O₃)@La₂O₃8c@Al5c). This stabilizing effect applies to the long-term deactivation constant as well (7.2 × 10⁻³ h⁻¹ to 4.8 × 10⁻³ h⁻¹).

As the number of Al₂O₃ ALD cycles increases in the (Ni/Al₂O₃)@La₂O₃8c catalysts, the peak rate decreases, but the stability improves (i.e., the deactivation constants decrease). Once the number of Al₂O₃ ALD cycles reaches 20, however, although the stability is better, the peak activity is comparable to the (Ni/Al₂O₃)@Al20c catalyst. The mass gain after 20 cycles of Al₂O₃ ALD on La₂O₃-doped and undoped catalysts are very similar, 50.4 % and 52.0%, respectively, and FIG. 2A suggests that most Ni particles are covered by Al₂O₃ by using 20 ALD cycles of Al₂O₃ ALD overcoat layer. (This should also be true with or without La₂O₃ doping.) However, in the presence of La₂O₃, the very long induction period observed for (Ni/Al₂O₃)@Al20c (~20 h) disappears (compare closed squares and closed circles in FIG. 4B). This suggests that different factors contribute to the magnitude of peak activity for the two catalysts.

TABLE 1

Summary of catalyst activity and deactivation properties

| Catalyst | Peak reaction rate (mmols_{CH4} min⁻¹ g_{cat}⁻¹)^{a} | Deactivation constant (10⁻³ h⁻¹)^{b} | (Rate at 45 h)/(peak rate) (-)^{c} |
|---|---|---|---|
| Ni/Al₂O₃ | 217.15 | 67.9 (9.4) | 0.13 |
| (Ni/Al₂O₃)@La8c | 201.58 | 89.8 (6.2) | 0.07 |
| (Ni/Al₂O₃)@La8c@Al5c | 131.91 | 19.6 (4.8) | 0.65 |
| (Ni/Al₂O₃)@La8c@Al10c | 46.06 | 18.7 (3.0) | 0.75 |
| (Ni/Al₂O₃)@La8c@Al20c | 6.64 | 2.3 (1.8) | 0.82 |
| (Ni/Al₂O₃)@Al5c | 16.51 | 52.1 (7.2) | 0.05 |
| (Ni/Al₂O₃)@Al20c | 5.51 | 7.7 (6.5) | 0.83 |

^{a} Peak activity over 48 h of time-on-stream. Except for (Ni/Al₂O₃)@Al20c, these values are initial activities (TOS = 0) of the catalyst. For (Ni/Al₂O₃)@Al20c catalyst, this value is at around 20 h of TOS due to long induction period.
^{b} Short-term deactivation constant is calculated from the time at the peak activity for 5 h. For (Ni/Al₂O₃)@Al20c, the range is from 20-25 h. Long-term deactivation constant is given in parentheses (calculated between 24-48 h of TOS).
^{c}Rate at 45 h is divided by the peak rate to depict overall deactivation behavior.

The results of Table 1 and the discussion above demonstrate an unexpected synergy in the combination of La₂O₃ doping and Al₂O₃ overcoating. That is, the catalytic activity and stability of the La₂O₃-doped and Al₂O₃ overcoated catalysts (particularly (Ni/Al₂O₃)@La8c@Al5c) substantially exceeds what would have been expected based on the performance of the catalysts using only La₂O₃ doping ((Ni/Al₂O₃)@La8c) and the catalysts using only Al₂O₃ overcoating (e.g., (Ni/Al₂O₃)@Al5c). Specifically, since (Ni/Al₂O₃)@La8c has minimal effect on the peak reaction rate and (Ni/Al₂O₃)@Al5c greatly suppresses the peak reaction rate, the peak reaction rate of (Ni/Al₂O₃)@La8c@Al5c is surprisingly high. In addition, since (Ni/Al₂O₃)@La8c significantly increases the short-term deactivation constant and (Ni/Al₂O₃)@Al5c only moderately decreases the short-term deactivation constant, the short-term deactivation constant of (Ni/Al₂O₃)@La8c@Al5c is surprisingly small. Moreover, while (Ni/Al₂O₃)@La8c and (Ni/Al₂O₃)@Al5c achieve only 7% and 5% of their peak rates at 45 h TOS, respectively, remarkably, (Ni/Al₂O₃)@La8c@Al5c retains about 65% of its peak rate at 45 h TOS. Finally, it is surprising that use of La₂O₃ in the (Ni/Al₂O₃)@La8c@Al20c catalyst is able to eliminate the induction period observed for the (Ni/Al₂O₃)@Al20c catalyst without La₂O₃ doping. Each of these results are further discussed below.

In this Example, several catalysts were doped with La₂O₃ (~ 1 wt.% relative to Ni). It is clear that La₂O₃ doping by itself does not prevent Ni sintering and does not enhance the initial activity (see open squares in FIGS. 4A-4B). This indicates that La₂O₃ doping does not increase the activity per Ni atom and implies that La does not influence Ni electronically. However, La₂O₃ doping followed by Al₂O₃ ALD results in the following behaviors: a) The peak activity observed for samples (Ni/Al₂O₃) without alumina overcoat is largely preserved after 5 cycles, b) The rate of deactivation by sintering is inhibited, and c) The induction period seen for the (Ni/Al₂O₃)@Al20c catalyst is eliminated.

When comparing the activity of La₂O₃-doped and undoped catalysts, ((Ni/Al₂O₃)@La₂O₃8c@Al5c and (Ni/Al₂O₃)@Al5c), there are two main differences. The La₂O₃-doped catalyst ((Ni/Al₂O₃)@La₂O₃8c@Al5c) has an 8-fold higher peak activity than the undoped catalyst (131.91 vs. 16.51 mmols_{CH4} min⁻¹ g_{cat}⁻¹), In addition, the La₂O₃-doped catalyst is more substantially more stable than its undoped counterpart as it retains 65% of the peak activity at 45 h TOS (undoped catalyst retains only 5%) and exhibits lower deactivation constants (both long-term and short-term). First, as mentioned above and shown in Table 1, La₂O₃ doping alone does not significantly affect the activity of Ni. That means the increased activity of the (Ni/Al₂O₃)@La₂O₃8c@Al5c catalyst is due to an 8-fold increase in the surface area of exposed Ni. The difference in mass gained from the overcoat with and without La₂O₃ (8.2% and 7.2%, respectively) cannot explain the 8-fold difference in active surface area. Rather, the activity difference must be due to structural differences in the Al₂O₃ overcoat layer on the two catalysts that lead to a much higher fraction of exposed Ni when La₂O₃ doping is used. Second, even though the La₂O₃-doped catalyst possesses a similar mass of Al₂O₃ overcoat layer, the stability is better than its undoped counterpart. This cannot be explained if the Al₂O₃ overcoat layers on the two catalysts are structurally similar. La₂O₃ doping creates an Al₂O₃ overcoat that is more efficient in anchoring (i.e., stabilizing) the Ni atoms that are released from Ni nanoparticles during catalyst sintering by Ostwald ripening. Without wishing to be bound to any theory, the following is hypothesized to explain the role of La₂O₃ doping: a) the La₂O₃ binds preferentially to under-coordinated NiO sites that lead to under-coordinated Ni atoms during DRM, and b) the La₂O₃-doped sites then act as preferred binding sites for the Al ALD precursor (i.e. TMA), and c) the deposited alumina clusters around these La₂O₃-doped sites, thereby enhancing the stability of the underlying Ni while simultaneously leaving more highly-coordinated Ni sites exposed and available for catalysis.

It is believed that the long induction period of the undoped catalyst ((Ni/Al₂O₃)@Al20c catalyst) is due to the formation of NiAl₂O₄ species and the slow reduction of Ni²⁺, including diffusion of Ni²⁺ from the bulk NiAl₂O₄ structure to metallic Ni particle. This active metallic Ni, which has been reductively extracted from the NiAl₂O₄ phase, then undergoes sintering, the main reason underlying catalyst deactivation. Without wishing to be bound to any particular theory, it is proposed that doping with La₂O₃ prevents the formation of the inactive phase NiAl₂O₄, while still retaining the beneficial stability-enhancing effects of the Al₂O₃ overcoat. By preventing the formation of NiAl₂O₄, metallic Ni active sites available for DRM can immediately form. In the present (Ni/Al₂O₃)@La₂O₃8c catalysts, the quantity of La₂O₃ with respect to Ni is low and La₂O₃ has no stabilizing effect on the Ni alone, therefore the possibility that La₂O₃ itself significantly encapsulates Ni to prevent reaction with the Al₂O₃ overcoat is excluded. Instead, by using microdomains of La₂O₃ on the Ni, lanthanum aluminate microdomains can form at Al-Ni interfaces, allowing the more reactive (such as surface or interface) Al ions to be stabilized so they do not proceed with surface or grain boundary restructuring to the corundum phase. Specifically, this is achieved by incorporating La cations into a more stable, localized perovskite aluminate structure and requires relatively little La to be in contact with the Al₂O₃. In contrast, formation of NiAl₂O₄ by incorporation of Ni²⁺ cations into the aluminate structure, which may temporarily stabilize Al ions at the Ni-Al boundary, is not thermodynamically favorable under DRM conditions because the energetic Ni²⁺ prefers reduction. Incorporation of La cations into the aluminate structure, specifically at Al-Ni interfaces, would eliminate the driving force for Ni²⁺ incorporation into the alumina structure, preventing the reaction of Ni with the Al₂O₃ overcoat. The portion of the Ni surface in proximity to La₂O₃ deposited by ALD therefore remains metallic and exposed to catalytic reagents, while the oxide overcoat can still provide stabilization against sintering through particle encapsulation and Ni-O-Al interactions.

Unlike existing catalyst preparation methodologies, the present Example demonstrates the use of very small amounts of La₂O₃ incorporated directly onto the surface of the Ni/Al₂O₃ catalyst via ALD, followed by subsequent application of a layer of ALD Al₂O₃ on top. The results presented show that these very small amounts of La₂O₃ on the surface are sufficient to promote Al₂O₃-supported Ni catalysts, rather than high amounts (~10 wt.%) that have been used in Al₂O₃ supports or when using La₂O₃ itself as the support.

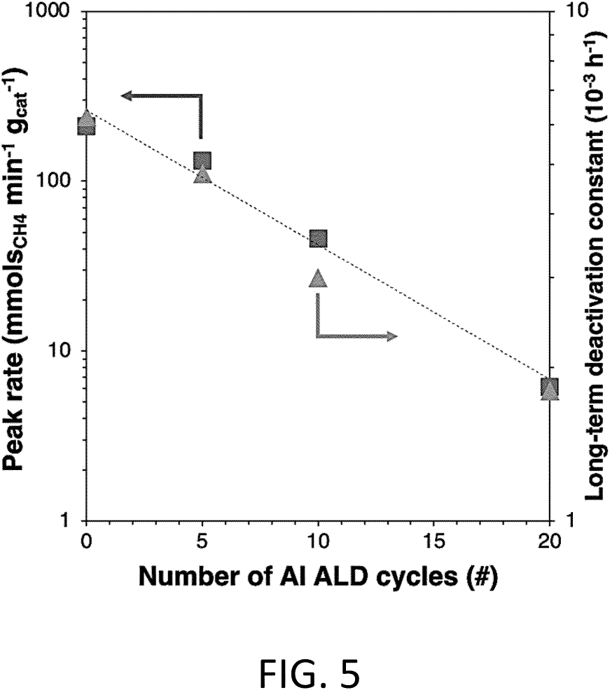

Finally, the effects of the number of Al₂O₃ ALD cycles on Ni/Al₂O₃@La₂O₃8c on the peak DRM catalytic activity and the long-term deactivation constant are shown in FIG. 5, clearly showing the trade-off between the peak rate and the deactivation constant. The lower the activity, the higher the stability on Al₂O₃ overcoating. For example, (Ni/Al₂O₃)@La₂O₃8c@Al10c (3.0 × 10⁻³ h⁻) catalyst deactivates faster than (Ni/Al₂O₃)@La₂O₃8c@Al20c (1.8 × 10⁻³ h⁻) in the long-term. The latter catalyst, however, has ~7-fold lower peak activity, 6.64 mmols_{CH4} min⁻¹ g_{cat}⁻¹ vs. 46.06 mmols_{CH4} min⁻¹ g_{cat}⁻¹. Thus, the number of Al₂O₃ ALD cycles can be used to optimize DRM catalysts and their performance.

### Conclusions

Deposition of La₂O₃ and Al₂O₃ via ALD was performed on an Al₂O₃-supported Ni DRM catalyst for operation at 700° C. La₂O₃ was doped first on the Ni/Al₂O₃ catalyst, followed by an ALD Al₂O₃ overcoat, varying the number of ALD growth cycles. Differences between bulk ICP and XPS surface compositional analysis indicate surface enrichment in both Ni and La. While Al₂O₃ covers Ni on the surface, La₂O₃ still appears to be present predominantly on the surface. Subsequent overcoating by Al₂O₃ appears to form a thin layer with the estimated growth rate of 0.9 Å/ALD cycle. La₂O₃ alone on Ni/Al₂O₃ does not significantly affect the DRM activity or stabilize the supported Ni catalyst. However, once the Al₂O₃ overcoating is applied on (Ni/Al₂O₃)@La₂O₃8c, the synergy of the combination achieves a powerful balance between activity and stability. Importantly, in the presence of La₂O₃ on the Al₂O₃-overcoated catalysts, activity loss by deactivation is significantly lowered vs the catalyst in the absence of La₂O₃. Moreover, the La₂O₃ addition reduces long catalytic induction period (~20 h) which has been attributed to NiAl₂O₄ formation. It is proposed that La₂O₃ induces an Al₂O₃ overcoat that leaves highly-coordinated Ni atoms exposed and available for catalysis. It is further proposed that La₂O₃ plays a role in preventing NiAl₂O₄ formation, keeping Ni in the active, metallic state, thereby affording higher peak catalytic activity and improved stabilization against sintering.

The word “illustrative” is used herein to mean serving as an example, instance, or illustration. Any aspect or design described herein as “illustrative” is not necessarily to be construed as preferred or advantageous over other aspects or designs. Further, for the purposes of this disclosure and unless otherwise specified, “a” or “an” means “one or more.”

If not already included, all numeric values of parameters in the present disclosure are proceeded by the term “about” which means approximately. This encompasses those variations inherent to the measurement of the relevant parameter as understood by those of ordinary skill in the art. This also encompasses the exact value of the disclosed numeric value and values that round to the disclosed numeric value.

The foregoing description of illustrative embodiments of the disclosure has been presented for purposes of illustration and of description. It is not intended to be exhaustive or to limit the disclosure to the precise form disclosed, and modifications and variations are possible in light of the above teachings or may be acquired from practice of the disclosure. The embodiments were chosen and described in order to explain the principles of the disclosure and as practical applications of the disclosure to enable one skilled in the art to utilize the disclosure in various embodiments and with various modifications as suited to the particular use contemplated. It is intended that the scope of the disclosure be defined by the claims appended hereto and their equivalents.

What is claimed is:

1. A catalyst system comprising an aluminum oxide support comprising nickel, a layer of a lanthanide oxide on a surface of the aluminum oxide support, and a layer of aluminum oxide on a surface of the layer of the lanthanide oxide.

2. The catalyst system of claim 1, wherein the lanthanide oxide is lanthanum oxide.

3. The catalyst system of claim 1, wherein the layer of the lanthanide oxide is in the form of a plurality of lanthanide oxide microdomains.

4. The catalyst system of claim 3, wherein more of the lanthanide oxide in the layer of the lanthanide oxide is positioned on the nickel of the aluminum oxide support than on the aluminum oxide of the aluminum oxide support.

5. The catalyst system of claim 3, wherein the plurality of lanthanide oxide microdomains are positioned on under-coordinated sites of the nickel of the aluminum oxide support.

6. The catalyst system of claim 3, wherein the layer of aluminum oxide is in the form of a plurality of aluminum oxide microdomains, the plurality of aluminum oxide microdomains positioned on surfaces of the plurality of lanthanide oxide microdomains.

7. The catalyst system of claim 1, wherein the catalyst system comprises no more than 5 weight% lanthanide and the nickel is present at an amount of from 1 weight% to 20 weight%.

8. The catalyst system of claim 7, wherein the layer of aluminum oxide has a thickness of from 0.2 nm to 10 nm.

9. A catalyst system comprising an aluminum oxide support comprising nickel, a plurality of lanthanide oxide microdomains on surfaces of the nickel of the aluminum oxide support, and aluminum oxide on surfaces of the plurality of lanthanide oxide microdomains.

10. The catalyst system of claim 9, wherein more of the lanthanide oxide in the plurality of lanthanide oxide microdomains is positioned on the surfaces of the nickel of the aluminum oxide support than on the aluminum oxide of the aluminum oxide support.

11. The catalyst system of claim 9, wherein the lanthanide oxide is lanthanum oxide.

12. The catalyst system of claim 9, wherein the plurality of lanthanide oxide microdomains are positioned on under-coordinated sites of the nickel of the aluminum oxide support.

13. The catalyst system of claim 9, wherein the aluminum oxide on surfaces of the plurality of lanthanide oxide microdomains is in the form of a plurality of aluminum oxide microdomains.

14. The catalyst system of claim 9, consisting of the nickel of the aluminum oxide support, the aluminum oxide of the aluminum oxide support, the lanthanide oxide of the plurality of lanthanide oxide microdomains, and the aluminum oxide on surfaces of the plurality of lanthanide oxide microdomains.

15. A method of making the catalyst system of claim 1, the method comprising:
(a) exposing the aluminum oxide support comprising nickel to cycles of alternating pulses of a lanthanide precursor and a first oxygen precursor under conditions to induce reactions to form a lanthanide oxide via atomic layer deposition (ALD), thereby forming the layer of the lanthanide oxide on the surface of the aluminum oxide support; and
(b) exposing the layer of the lanthanide oxide on the surface of the aluminum oxide support to cycles of alternating pulses of an aluminum precursor and a second oxygen precursor under conditions to induce reactions to form aluminum oxide via ALD, thereby forming the layer of aluminum oxide on the layer of the lanthanide oxide.

16. The method of claim 15, wherein the lanthanide oxide is lanthanum oxide.

17. The method of claim 15, wherein from 2 to 20 cycles of alternating pulses of the lanthanide precursor and the first oxygen precursor are used.

18. The method of claim 17, wherein from 5 to 30 cycles of alternating pulses of the aluminum precursor and the second oxygen precursor are used.

19. A method of methane reforming, the method comprising exposing the catalyst system of claim 1 to methane and an oxygen containing compound at an elevated temperature and for a period of time to convert the methane to products.

20. The method of claim 19, wherein the oxygen containing compound is CO₂ and the products comprise H₂ and CO.
